(19) United States
(12) Patent Application Publication
(10) Pub. No.: US 2012/0146175 A1
(43) Pub. Date: Jun. 14, 2012

(54) INSULATING REGION FOR A SEMICONDUCTOR SUBSTRATE

(76) Inventors: Nicolas Loubet, Guilderland, NY (US); Qing Liu, Guilderland, NY (US); Sanjay C. Mehta, Niskayuna, NY (US); Spyridon Skordas, Troy, NY (US)

(21) Appl. No.: 12/963,715

(22) Filed: Dec. 9, 2010

(51) Int. Cl. H01L 29/02; H01L 21/762

(52) U.S. Cl. 257/506; 438/479; 257/E21.561; 257/E29.002

(57) ABSTRACT

An insulating region for a semiconductor wafer and a method of forming same. The insulating region can include a tri-layer structure of silicon oxide, boron nitride and silicon oxide. The insulating region may be used to insulate a semiconductor device layer from an underlying bulk semiconductor substrate. The insulating region can be formed by coating the sides of a very thin cavity with silicon oxide, and filling the remainder of the cavity between the silicon oxide regions with boron nitride.

### BACKGROUND OF THE INVENTION

1. Field of Invention

The techniques described herein relate to generally to forming an insulating region in a semiconductor substrate and more particularly to forming a tri-layer insulating region of oxide/boron nitride/oxide between a semiconductor device layer and a bulk semiconductor substrate.

2. Discussion of the Related Art

Various types of wafers are used in integrated circuit manufacturing, including single crystal semiconductor wafers and silicon-on-insulator (SOI) wafers. SOI wafers can provide advantages in certain applications because the insulating layer provides electrical isolation between the silicon device layer and the underlying silicon substrate. Field effect transistors formed in the silicon device layer have a channel region that extends laterally along the silicon device layer. The silicon device layer typically has a thickness of about 70 nm.

Forming thinner channels can enable better control of transistor operation. To form thinner channel regions, an SOI wafer is polished to reduce the thickness of the silicon device layer to about 6-8 nm. However, polishing the wafer to reduce its thickness adds additional manufacturing cost and can introduce non-uniformities in the silicon device layer.

### SUMMARY

Some embodiments relate to a method of forming an insulating region that includes forming a cavity between a first semiconductor region and a second semiconductor region. The interior of the cavity is coated with a first insulating material. The cavity is filled with a second insulating material between portions of the first insulating material.

Some embodiments relate to a method of forming an insulating region. The method includes forming a first layer comprising silicon oxide, forming a second layer comprising silicon oxide; and forming a third layer comprising boron nitride between the first and second layers.

Some embodiments relate to a semiconductor structure that includes a first semiconductor region; a first insulating layer of a first material over the first semiconductor region; a second insulating layer of a second material over the first insulating layer; a third insulating layer of the first material over the second insulating layer; and a second semiconductor region over the third insulating layer.

The foregoing is a non-limiting summary of some embodiments of the invention.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the invention.

FIG. 1 shows a cross section of a semiconductor structure that includes a sacrificial semiconductor layer between a semiconductor device layer and the bulk semiconductor substrate, according to some embodiments.

FIG. 2 illustrates the removal of the sacrificial semiconductor layer to form a cavity.

FIG. 3 shows a step of forming an oxide layer on the top and bottom of the cavity.

FIG. 4 shows a step of filling the cavity with a boron nitride layer between the top and bottom oxide layers.

FIG. 5 shows a step of etching the boron nitride layer.

### DETAILED DESCRIPTION

The techniques described herein relate to the formation of an insulating region for insulating a semiconductor device layer from the underlying bulk semiconductor substrate. In some embodiments, the insulating region is formed of a tri-layer of silicon oxide, boron nitride and silicon oxide positioned between the device layer and the underlying bulk semiconductor substrate. Advantageously, the oxide and nitride materials of the tri-channel layer can be deposited in a highly-conformal manner that enables the tri-channel layer to be formed in a thin cavity beneath the device layer.

In some embodiments, the insulating region insulates the semiconductor device layer from the underlying bulk semiconductor substrate in a manner similar to that of the insulating layer of an SOI wafer. The use of a bulk semiconductor substrate and a semiconductor device layer that is insulated according to the techniques described herein can enable reductions in costs compared to the use of an SOI wafer, as bulk semiconductor wafers can be less expensive than SOI wafers. Another advantage is that the device layer can be formed to have any suitable thickness using epitaxial growth or another deposition method, and processing steps to remove semiconductor material are not required to achieve a desired channel thickness.

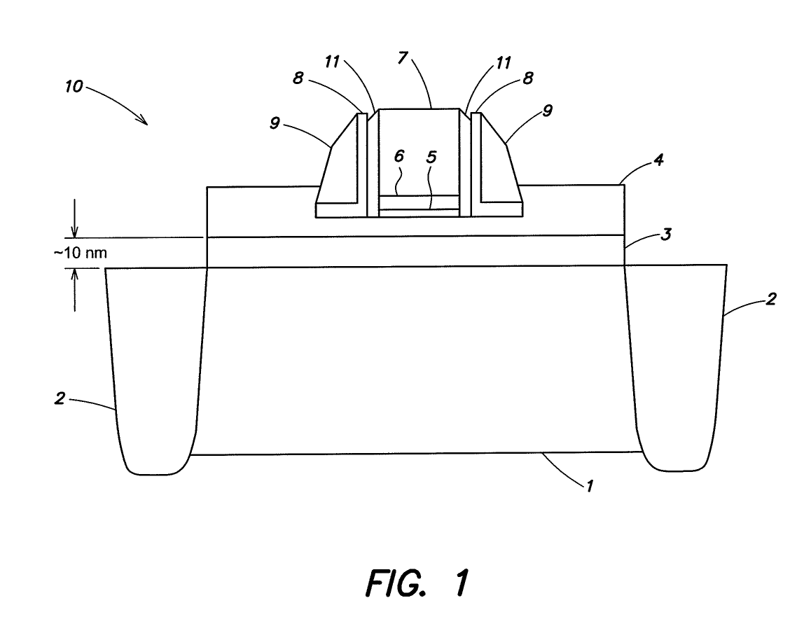

The insulating region can be formed by removing a sacrificial semiconductor layer between the device layer and the underlying bulk semiconductor substrate and by conformally depositing layers of insulating material within the resulting cavity. Oxide can be conformally deposited on the top and bottom of the cavity, and the remaining portion of the cavity can be filled with a conformal deposition of boron nitride. Advantageously, the resulting tri-layer insulating region can have a low dielectric constant and a high wet etch resistance to HF (hydrofluoric acid). In addition, the boron nitride material may be used to form a low-k, etch resistant spacer material adjacent to the transistor gate. An example of a technique for forming such an insulating region is described below with reference to FIGS. 1-5.

FIG. 1 shows a cross section of a semiconductor structure 10 that includes a portion of a bulk semiconductor substrate 1, insulating trenches 2, a sacrificial layer 3, a semiconductor device layer 4, a gate dielectric 5, a titanium nitride layer 6, a gate 7, a silicon oxide insulating layer 8, a silicon nitride spacer layer 9 and an additional silicon nitride layer 11.

The bulk semiconductor substrate 1 may be a formed of single crystal semiconductor material, such as single crystal silicon. For purposes of illustration, only a portion of bulk semiconductor substrate 1 is shown in FIGS. 1-5. Insulating trenches 2 can be formed in the semiconductor structure 10. The insulating trenches 2 may be formed of silicon oxide or any other suitable insulating material. A sacrificial layer 3 can be formed above the bulk semiconductor substrate 1. Sacrificial layer 3 can be removed later to form a cavity under the semiconductor device layer 4, which may be filled with insulating material. In some embodiments, sacrificial layer 3 may be formed of SiGe using an epitaxial deposition process. However, any suitable sacrificial material or deposition process may be used. In some embodiments, the sacrificial layer 3 is selectively etchable with respect to the semiconductor material forming the bulk semiconductor substrate 1 and the semiconductor device layer 4 to facilitate removal of the sacrificial layer. The sacrificial layer 3 may be thin, such as on the order of ˜10 nm. A semiconductor device layer 4 can be formed on the sacrificial layer 3. Semiconductor device layer 4 may be formed of single crystal silicon or any other suitable semiconductor material. The thickness of semiconductor device layer 4 may be small, such as on the order of about ˜6-8 nm or smaller, which can enable the formation of transistors with narrow channels. The semiconductor device layer 4 may be formed by epitaxial deposition or using any other suitable process. A gate dielectric 5 can be formed on the semiconductor device layer 4. Gate dielectric 5 may be formed of any material suitable for insulating a transistor gate, such as SiON. A region of TiN 6 can be formed over the gate dielectric 5. A gate 7 formed of polysilicon or any other suitable material can be formed over the TiN region. Further insulating layers including silicon oxide regions 8, silicon nitride spacer regions 9 and additional silicon nitride regions 11 can be formed around the gate region.

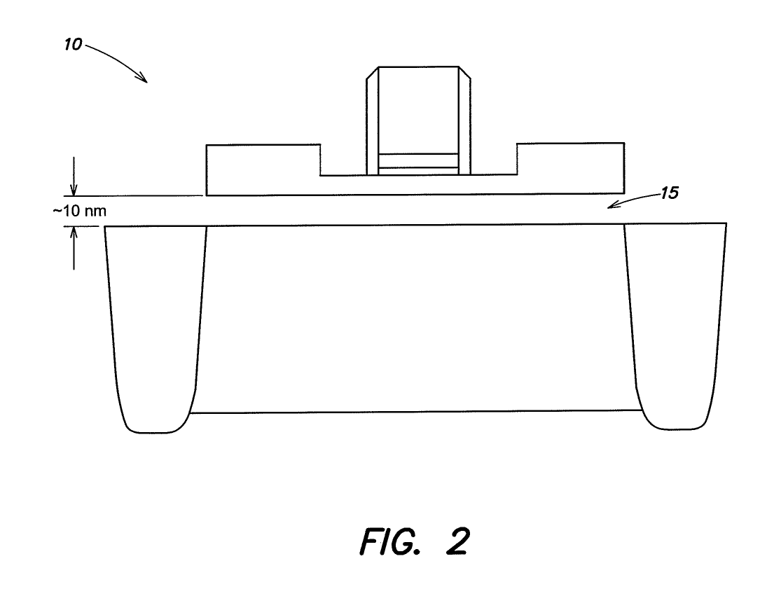

FIG. 2 illustrates the step of removing sacrificial layer 3. Sacrificial layer 3 may be removed using RIE (reactive ion etching) or any other suitable etching process. The etching process can preferentially etch sacrificial layer 3 with respect to the bulk semiconductor substrate 1 and semiconductor device layer 4. As shown in FIG. 2, removing sacrificial layer 3 creates a buried cavity 15 beneath the semiconductor device layer 4. Buried cavity 15 may have a relatively small thickness on the order of about ˜10 nm.

After the cavity 15 is formed, an insulating region can be formed within the cavity to insulate the semiconductor device layer 4 from the bulk semiconductor substrate 1. In some embodiments, a conformal deposition of silicon oxide and boron nitride can fill the narrow cavity 15 between the semiconductor device layer 4 and the bulk semiconductor substrate 1.

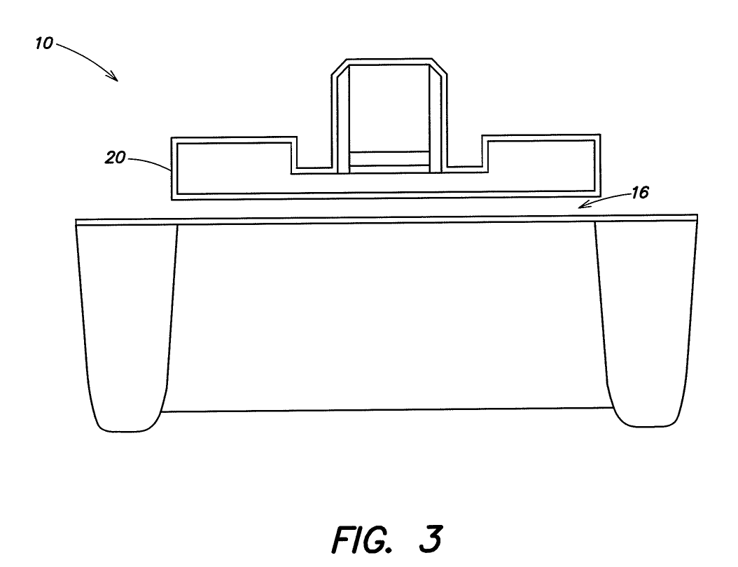

FIG. 3 illustrates a step of forming a first insulating material within the cavity. The top and bottom of the cavity can be coated with a first insulating material 20, which can be formed of silicon oxide or any other suitable insulating material. The first insulating material may also be formed on the semiconductor device layer 4 and the gate 7. In some embodiments, the insulating material may be deposited using a conformal coating process such as PEALD (Plasma-Enhanced Atomic Layer Deposition) or PECVD (Plasma-Enhanced Chemical Vapor Deposition). The parameters of the deposition process may be optimized to enable the insulating material to extend along the entire length of the cavity 15, without gaps in the center of the cavity in the area farthest to from the cavity's edge. If silicon oxide is used as the first insulating material 20, the oxide can provide a relatively high breakdown field and low leakage characteristics. After deposition of the first insulating material on the top and bottom of the cavity 15, a thin cavity 16 may remain between the upper and lower layers of the first insulating material 20.

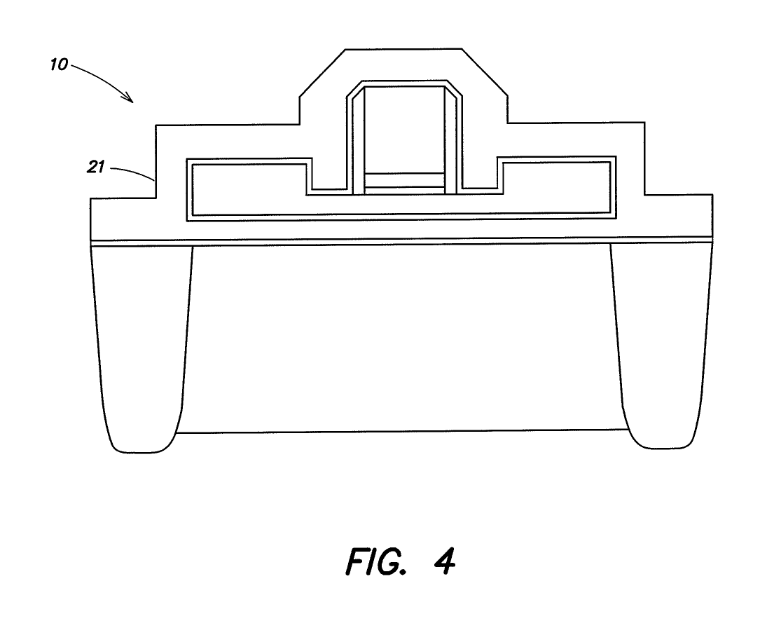

FIG. 4 shows a step of filling the remaining thin cavity 16 using a second insulating material 21. The second insulating material 21 may also be formed above the semiconductor device layer 4 and the gate 7. The second insulating material 21 may be different from the first insulating material 20. In some embodiments, the second insulating material 21 may be boron nitride (BN). Advantageously, BN is capable of filling the thin cavity 16, which may be only a few nanometers thick. The layers of first insulating material 20 above and below the boron nitride layer can reduce the diffusion of boron out of the boron nitride layer.

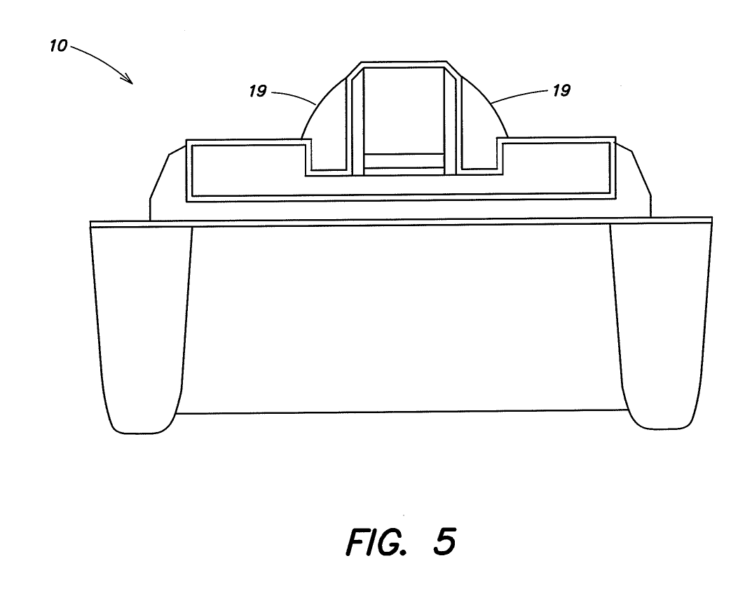

FIG. 5 shows a step of etching back the second insulating material 21 to form boron nitride spacers 19 adjacent to the gate 7. An advantage of BN as a spacer material that it has excellent wet etching resistance in hydrofluoric acid (HF), which can provide robustness during wet etching processes. A further advantage of BN is that it is a relatively low k dielectric material. The second insulating material may be etched using reactive ion etching (RIE) or any other suitable etching process. A silicidation process may also be performed after forming the spacer regions.

### Examples of Processes for Silicon Oxide and Boron Nitride Deposition

When silicon oxide is used as the first insulating material 20 and boron nitride is used as the second insulating material 21, these materials may be deposited using Plasma-Enhanced Atomic layer Deposition (PEALD) or Pulsed Plasma-Enhanced Chemical Vapor Deposition (Pulsed PECVD). Examples of process steps and process parameters for forming these layers will now be described. It should be appreciated that these are only examples of process steps and parameters, and others could be used.

The PEALD processes can start with the introduction of the wafer in the deposition chamber at a suitable temperature. Once temperature, pressure and inert gas flows are stable, the first process step is to expose the wafer to precursor A flow so that the precursor A molecules adsorb on the substrate to form a saturated layer on its surface. At this point there can be a HFRF plasma step to promote the reaction/seeding of this layer on the surface. This step can be followed by a purging step with inert gas, to remove excess precursor A from the chamber, with only the saturated layer adsorbed/bonded on the surface remaining. In the next step, the substrate can be exposed to flow of precursor B (oxidizing or nitridation precursor), at which point precursor B molecules adsorb to form a saturated layer on the surface of the wafer, but do not react yet with the precursor layer. At the next step, plasma can be initiated in order to provide the energy for the oxidation/nitridation reaction. Due to the fact that the precursor A supply may be limited to one saturated layer on the surface, the oxidation/nitridation reaction can be limited by the supply of precursor A. Therefore the process is self-limiting, which results in a film of specific thickness for each cycle. By repeating the exposure of the substrate in cyclical fashion of: Precursor flow A; Plasma (seed); Purge; Precursor flow B; Plasma (reaction); and Purge, the result is a film of high conformality and uniformity, with very good thickness control, as the thickness of the film can be set by the number of cycles used.

In pulsed PECVD processes the precursors can flow at the same step in short pulses and the reaction can be initiated by plasma at the same time. The deposition can be done in pulses separated by inert gas to keep the growth rate low to have better uniformity and conformality, as well as better thickness control, again set by the number of deposition pulses/cycles.

For the silicon oxide formation processes the following exemplary process parameters may be used.
Temperature range: 100 C to 400 C
Pressure range: 1-10 torr
Silicon precursors: OMCTS, TEOS, Silane
Oxidizing precursors: O2, N2O
OMCTS/TEOS liquid flow range: 1-10 mg/min
OMCTS/TEOS carrier gas flow range: Ar @ 1000-10000 sccm
Silane gas flow range: 100 sccm-5000 sccm
Oxidizer flow range: O2 @ 500-5000 sccm
Inert purging gas flow range: Ar @ 1000-20000 sccm
HFRF plasma power for initiating reaction: 50-500 W

For the boron nitride formation processes the following exemplary process parameters may be used.
Temperature range: 100 C to 500 C
Pressure range: 1-10 torr
Boron precursors: Diborane
Nitridation precursors: NH3
Diborane flow range: 100-10000 sccm
Nitridation precursor flow range: NH3 @ 100-10000 sccm
Inert purging gas flow range: Ar @ 1000-20000 sccm
HFRF plasma power for initiating reaction: 50-500 W

This invention is not limited in its application to the details of construction and the arrangement of components set forth in the foregoing description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method of forming an insulating region, the method comprising:
forming a cavity between a first semiconductor region and a second semiconductor region;
coating an interior of the cavity with a first insulating material; and
filling the cavity with a second insulating material between portions of the first insulating material.

2. The method of claim 1, further comprising:
forming a sacrificial layer over a semiconductor substrate;
forming a semiconductor device layer over the sacrificial layer; and
removing the sacrificial layer to form the cavity.

3. The method of claim 1, wherein coating the interior of the cavity with a first insulating material comprises coating the interior of the cavity with silicon oxide.

4. The method of claim 1, wherein coating the interior of the cavity comprises coating a top and a bottom of the cavity with the first insulating material.

5. The method of claim 1, wherein the cavity is filled with boron nitride between the portions of the first insulating material.

6. The method of claim 5, further comprising forming a boron nitride spacer region adjacent to the gate of a transistor.

7. A method of forming an insulating region, the method comprising:
forming a first layer comprising silicon oxide;
forming a second layer comprising silicon oxide; and
forming a third layer comprising boron nitride between the first and second layers.

8. The method of claim 7, wherein the first, second and third layers are formed in a cavity between a semiconductor device layer and a semiconductor substrate.

9. The method of claim 8, wherein the cavity is no greater than about 10 nm thick.

10. The method of claim 8, further comprising:
forming a sacrificial layer over the semiconductor substrate;
forming the semiconductor device layer over the sacrificial layer; and
removing the sacrificial layer to form the cavity.

11. A semiconductor structure, comprising:
a first semiconductor region;
a first insulating layer of a first material over the first semiconductor region;
a second insulating layer of a second material over the first insulating layer;
a third insulating layer of the first material over the second insulating layer; and
a second semiconductor region over the third insulating layer.

12. The semiconductor structure of claim 11, wherein the first material comprises silicon oxide.

13. The semiconductor structure of claim 11, wherein the second material comprises boron nitride.

14. The semiconductor structure of claim 11, wherein the first and second semiconductor regions are separated by no more than about 10 nm.

15. The semiconductor structure of claim 11, wherein the first semiconductor region comprises a bulk semiconductor substrate.

16. The semiconductor structure of claim 11, wherein the first and second semiconductor regions comprise single crystal silicon.

17. The semiconductor structure of claim 11, wherein the second semiconductor region has a thickness of no greater than about 8 nm.
